(19) United States
(12) Patent Application Publication
(10) Pub. No.: US 2008/0050637 A1
(43) Pub. Date: Feb. 28, 2008

(54) Microfabricated Fuel Cell

(75) Inventors: Shruti Prakash, Atlanta, GA (US); Paul A. Kohl, Atlanta, GA (US); Dhananjay Bhusari, Stone Mountain, GA (US)

Correspondence Address: STOEL RIVES LLP - SLC, 201 SOUTH MAIN STREET, ONE UTAH CENTER, SALT LAKE CITY, UT, 84111, US

(73) Assignee: GEORGIA TECH RESEARCH CORPORATION, Atlanta, GA (US)

(21) Appl. No.: 11/843,634

(22) Filed: Aug. 22, 2007

Related U.S. Application Data
(60) Provisional application No. 60/839,182, filed on Aug. 22, 2006.

(51) Int. Cl. H01M 8/02; C23C 16/00

(52) U.S. Cl. 429/34; 427/569; 427/97.5

(57) ABSTRACT

One or more microfabricated fuel cells may be integrated into a printed circuit board or a printed wiring board within an electronic device. The electrical energy created by the integrated microfabricated fuel cells within the metal wiring on the PWB may then be used by the electronic components within and on the PWB.

### RELATED APPLICATIONS

This application claims priority from U.S. Provisional Patent Application Ser. No. 60/839,182, titled “IMPROVEMENT TO MICROFABRICATED FUEL CELL,” filed Aug. 22, 2006, which is incorporated by reference in its entirety.

### TECHNICAL FIELD

The invention relates generally to the field of fuel cells and, more specifically to the field of microfabricated fuel cells integrated within a device.

### BRIEF DESCRIPTION OF THE DRAWINGS

FIG. 1 is a cross-sectional view of a fuel cell.

FIGS. 2A-2I show an exemplary process for fabrication of an integrated microfabricated fuel cell.

FIG. 3A-3I show an alternative exemplary process for fabrication of an integrated microfabricated fuel cell.

FIG. 4 depicts a representational cross section of inverted fuel cells in series.

FIG. 5 shows a Current vs. Voltage curve for one embodiment of an integrated microfabricated fuel cell.

### DETAILED DESCRIPTION OF THE EMBODIMENTS

It will be readily understood that the components of the embodiments as generally described and illustrated in the figures herein could be arranged and designed in a wide variety of different configurations. Thus, the following more detailed description of various embodiments, as represented in the figures, is not intended to limit the claim scope, but is merely representative of various embodiments. While the various aspects of the embodiments are presented in drawings, the drawings are not necessarily drawn to scale unless specifically indicated.

As those of skill in the art will appreciate, the principles disclosed herein may be applied to and used with a variety of fuel cell systems including an inorganic or organic fuel cell, direct methanol fuel cell (DMFC), reformed methanol fuel cell, direct ethanol fuel cell, polymer electrolyte membrane fuel cell (PEMFC), microbial fuel cell, reversible fuel cell, formic acid fuel cell, and the like. Furthermore, the present invention may be used in a variety of applications and with fuel cells of various sizes and shapes. For purposes of example only, and not meant as a limitation, the embodiments disclosed herein may be used for electronic battery replacement, mini and microelectronics, car engines, power plants, and as an energy source in many other devices and applications.

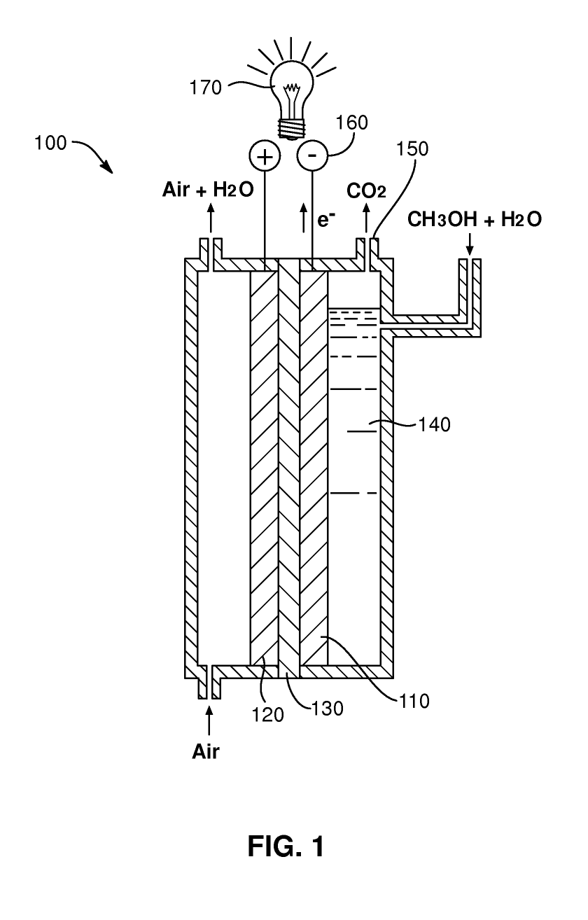

With reference to the accompanying figures, particular embodiments will now be described in greater detail. As shown by FIG. 1, a typical fuel cell 100 may include an anode 110 and a cathode 120 separated by a proton-exchange membrane (PEM) 130. The anode 110 may be disposed on one side of the PEM 130 and the cathode 120 disposed on the opposite side of the PEM. A fuel 140, such as liquid methanol, is oxidized at the anode 110, in the presence of a catalyst, (i.e., Pt—Ru) and water (H₂O), to produce electrons (e⁻), protons (H⁺), and carbon dioxide (CO₂). The fuel cell 100 may include a vent 150 to allow the escape of reaction gasses, such as CO₂ gas. The electrons flow from the anode 110 to the cathode 120 through an external circuit 160 to deliver electrical energy to an attached electrical device or storage device 170. Meanwhile, the protons (H⁺) pass through the PEM 130 and combine with oxygen (O₂), in the presence of a catalyst, to form water at the cathode 120.

One example of a fuel cell is a direct organic fuel cell which may use hydrocarbon fuels, such as diesel, methanol, ethanol, and chemical hydrides. One embodiment may include a direct methanol fuel cell (DMFC), a type of proton-exchange fuel cell where the methanol fuel is fed directly to the fuel cell. The anode and cathode reactions in a DMFC can be expressed as follows:

$$Anode \text{:} {CH}_{3} OH + {H}_{2} O {\to }^{Pt - Ru} {CO}_{2} + 6 {H}^{+} + 6 {e}^{-}$$

$$Cathode \text{:} 6 {H}^{+} + 6 {e}^{-} + 1.5 {O}_{2} {\to }^{Pt} 3 {H}_{2} O$$

An example of an DMFC is an integrated microfabricated fuel cell that can be constructed within an electrical device. In one embodiment, one or more microfabricated fuel cells are built into a substrate such as a printed circuit board (PCB) or a printed wiring board (PWB) within an electronic device. The PCB and the PWB may be epoxy fiber glass construction. The electrical energy that may be created by the integrated microfabricated fuel cells on the PWB can be used by the electronic components within and on the PWB. This is advantageous because the power source does not have to be separately packaged, have separate wiring, and have a separate enclosure. Also, a device with an integrated microfabricated fuel cell may be smaller without having to depend on a bulky battery as the power source. Further, an integrated microfabricated fuel cell may use a liquid power source, such as methanol, stored within a container of any shape and can be flexible so as to conform to available space.

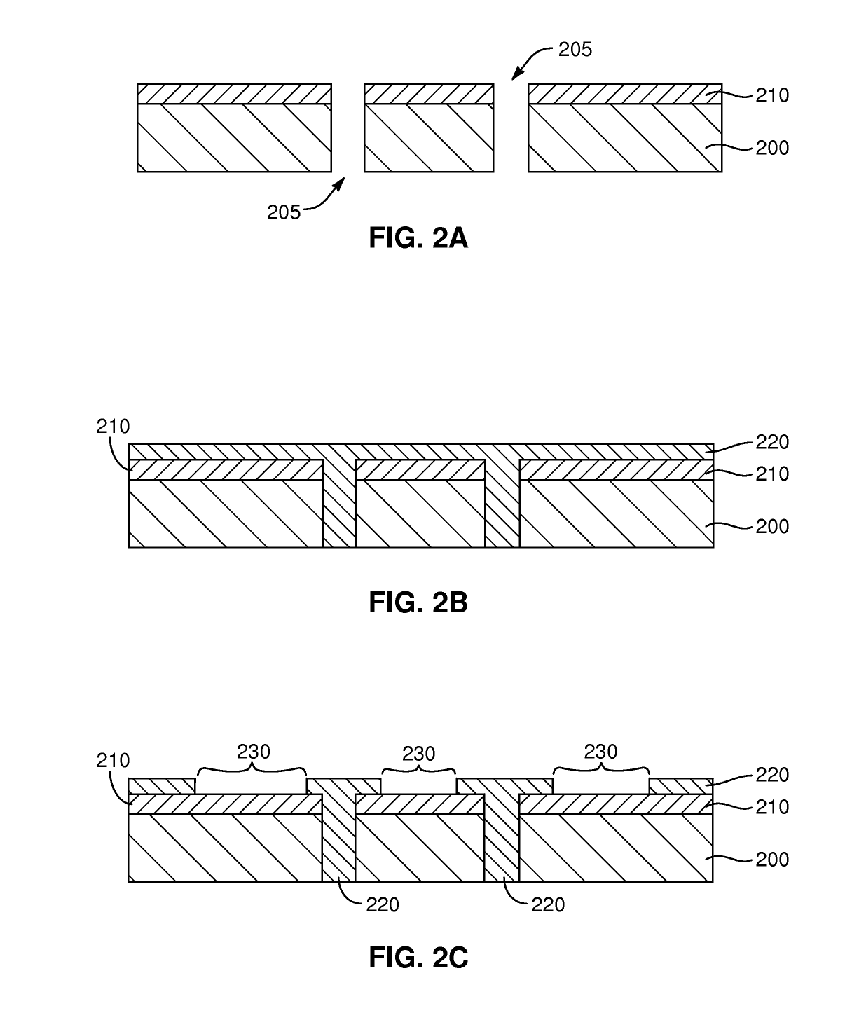

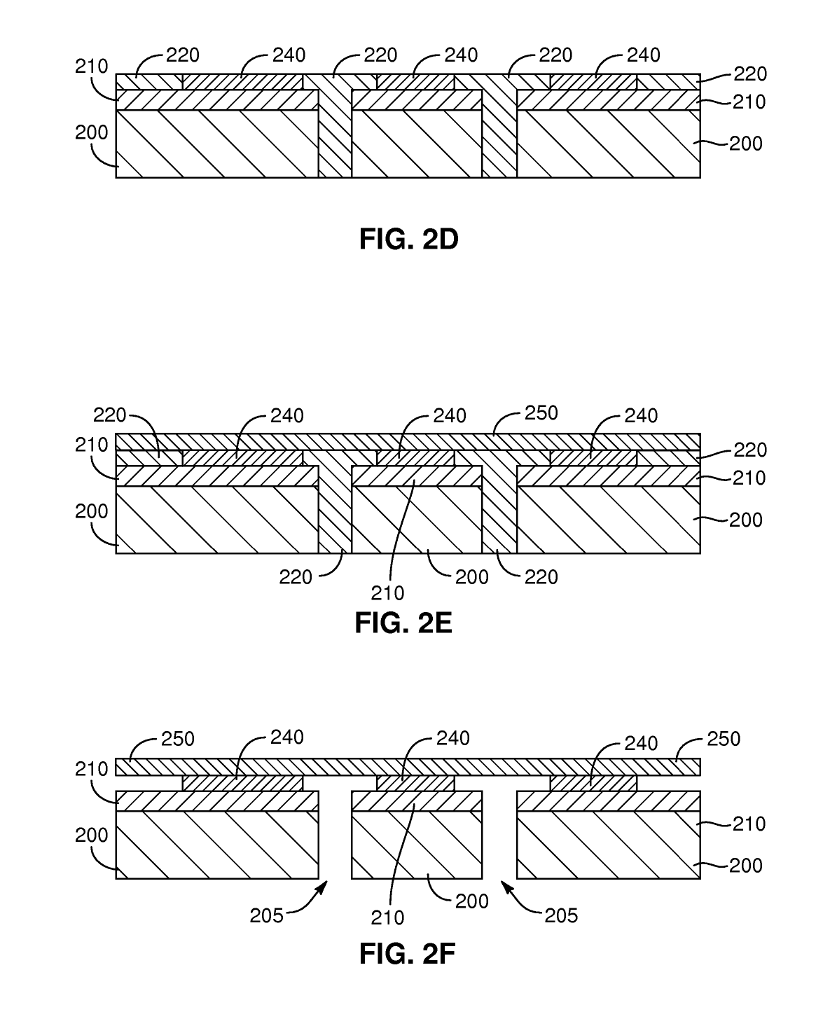

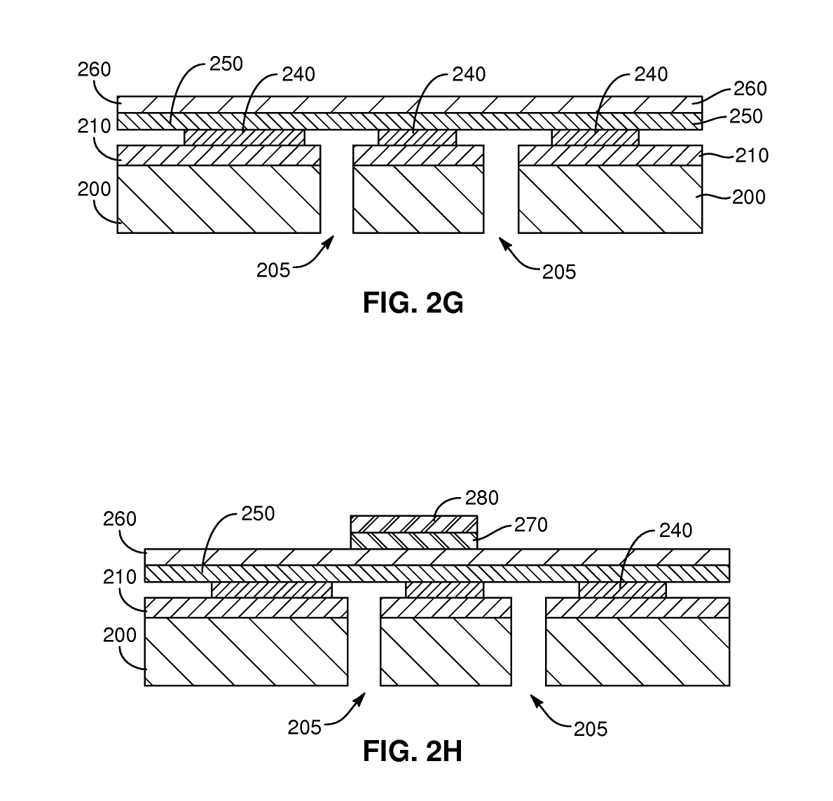

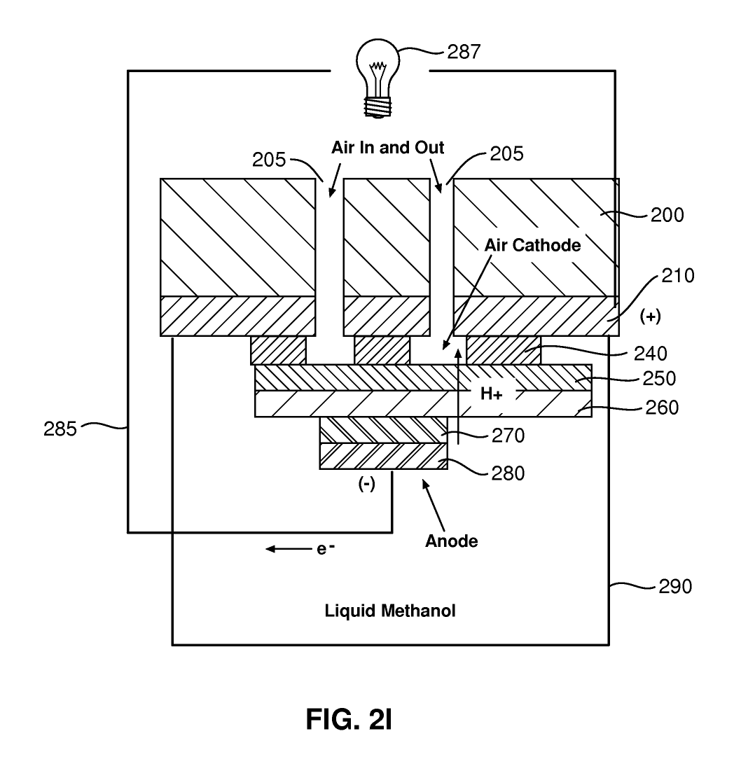

Referring to FIGS. 2A-2B, the process of making an integrated microfabricated fuel cell on a PCB or PWB may include patterning of the fuel cell structures with a sacrificial polymer. FIG. 2A represents a cross-sectional view of a PWB 200 after the deposition of a cathode current collector 210 and the drilling of one or more air holes such as air holes 205. In one embodiment, the air holes 205 and the cathode current collector 210 may be sized as desired. For example, the air holes 205 may be approximately 20-200 micrometers (μm) wide and the cathode current collector 210 may be approximately 100-1000 Å thick. The PWB 200 may be a blank PWB or it may be a pre-fabricated PWB with the desired circuits in place. The cathode current collector 210 may be sputtered on the surface of the PWB 200 and may include layers of titanium (Ti), gold (Au), copper (Cu), chromium (Cr), tungsten (W), tantalum (Ta), and other appropriate conductors. For example, the cathode current collector 210 may include a 200 Å layer of titanium sputtered directly on the PWB 200 and a 600 Å layer of gold sputtered on the layer of titanium.

Now with reference to FIG. 2B, after the one or more air holes 205 are drilled, a sacrificial polymer 220 may be spin coated on the surface of the cathode current collector 210 and within the air holes 205. The sacrificial polymer 220 may be polished to remove any excess polymer. The sacrificial polymer 220 may comprise a poly(propylene-carbonate) (PPC) and a photoacid generator (PAG) and serve as a temporary placeholder in the microfabrication process. For example, after overcoating with additional fuel cell structures, the polymer can be converted into a gas through polymer decomposition. The gaseous polymer products can permeate through the overcoating and the resulting air-cavity can be used to form systems of microchannels to deliver air and fluid to the microfabricated fuel cell. A photo-patternable sacrificial polymer can be made by combining the polymer with the PAG. Upon ultraviolet (UV) irradiation, a PAG can produce an acid which can catalytically decompose the sacrificial polymer 220. A number of different PAG can be used when forming the sacrificial polymer 220 such as 4-methylphenyl[4-(1-methylethyl)phenyl], iodonium tetrakis(pentafluorophenyl)borate, and others. In one embodiment, the sacrificial polymer 220 may comprise a mixture of approximately 20% by weight of PPC and approximately 5% by weight of PAG in an organic solvent such as γ-butyrolactone (GBL). After the sacrificial polymer 220 is spin cast on the cathode current collector 210, it may be soft baked to remove the solvent from the polymer.

As show in FIG. 2C, the sacrificial polymer 220 may be patterned with one or more channels such as channels 230. The channels 230 may be formed by exposing the photo-patternable sacrificial polymer 220 to ultraviolet (UV) light and heat. The sacrificial polymer 220 that is exposed to the UV light can then be removed during development by thermal decomposition. In one embodiment, the sacrificial polymer 220 may be patterned by exposure to approximately 248 nm light at 1 J/cm². For example, the exposed sacrificial polymer 220 may be developed and removed by thermal decomposition at approximately 190° C. for about 25 minutes.

Referring to FIG. 2D, the remaining sacrificial polymer 220 defines the channels 230 which may be electroplated with a conductor compatible with the cathode current collector 210. For example, as shown in FIG. 2D, channels 230 may be electroplated with gold or copper to create one or more channel walls 240. The channel walls 240 can be approximately 30-100 μm thick, which are in electrical communication with the cathode current collector 210.

FIG. 2E shows that a cathode catalyst/glass membrane layer 250 can be deposited over the sacrificial polymer 220 and the channel walls 240. For example, the cathode catalyst may be deposited by sputtering or painting a prepared catalyst ink containing carbon-supported platinum (Pt) on the surface of the remaining sacrificial polymer 220 and the channel walls 240. Over the cathode catalyst, a phosphorus doped silicon dioxide glass (P-SiO₂) of approximately 6-9 μm thick may be deposited using a plasma enhanced chemical vapor deposition (PECVD) system.

As shown by FIG. 2F, the sacrificial polymer 220 may be thermally decomposed thereby reopening the air holes 205. For example, the sacrificial polymer 220 may be thermally decomposed by being exposed in an oven to a slow temperature ramp up to approximately 190° C. With the air holes 205 free from obstruction, the oxygen from the air may be free to contact the cathode catalyst and be used as the oxidant at the cathode of the microfabricated fuel cell.

Referring to FIGS. 2G and 2H, a composite membrane layer approximately 15-50 μm thick may be deposited over the cathode catalyst/glass membrane layer 250. For example, a proton exchange membrane (PEM) 260 comprising commercially available Nafion (a perfluorinated polymer with sidechains terminated with sulfonic acid) or a phosphorus-doped silicon dioxide glass, deposited by PECVD, may be fabricated over the cathode catalyst/glass membrane layer 250. The PECVD method of creating the PEM 260 may be effective for fabrication of a fuel cell on silicon or PWB substrates since PECVD deposition of the PEM 260 can offer integration of the fuel cell fabrication process with the conventional CMOS process flow for device fabrication.

With continued reference to FIG. 2H, an anode catalyst 270 and an anode current collector 280 may be deposited on the PEM 260 opposite the air holes 205. For example, the anode catalyst 279 may comprise a platinum-ruthenium alloy layer sputter deposited on the surface of the PEM 260 or a carbon-supported Pt—Ru catalyst ink painted on the surface of the PEM 260. The anode current collector 280 may include a gold layer or other conductive layer deposited on the anode catalyst 270.

FIG. 2I shows a cross-sectional view of a completed microfabricated fuel cell made according the disclosure and embodiments herein. In FIG. 2I, the assembly from FIG. 2H has been inverted and a fuel reservoir, such as fuel reservoir 290, may be attached on the anode side to contain a liquid fuel that is oxidized by the microfabricated fuel cell. In one embodiment, an 8-12 molar (M) aqueous methanol solution may be used as fuel to power the microfabricated fuel cell. The inverted microfabricated fuel cell may be advantageous because the liquid fuel may be preventing from contact the PWB 200 substrate which may cause delamination of the epoxy fiberglass construction.

With continued reference to FIG. 2I, in order to power an integrated electrical storage device or electrical device, such as electrical device 287, the external power circuit 285 can be connected to the circuitry of the PWB or other electrical device such as electrical device 287. The external power circuit 285 may include an electrical circuit extending from the anode current collector 280 to the electrical device 287, and continuing to the cathode current collector 210. In this way, the external power circuit 287 allows the electrons produced by the oxidation of the fuel at the anode to move from the anode, through the electrical device 287, and then back to the cathode. As discussed previously, protons generated at the anode may pass through the PEM 260 and combine with oxygen in the air holes 205, and the electrons coming back from the external circuit 287, to form water on the cathode. The oxygen in the air holes 205 may be provided by the ambient air either passively or by a forced air system.

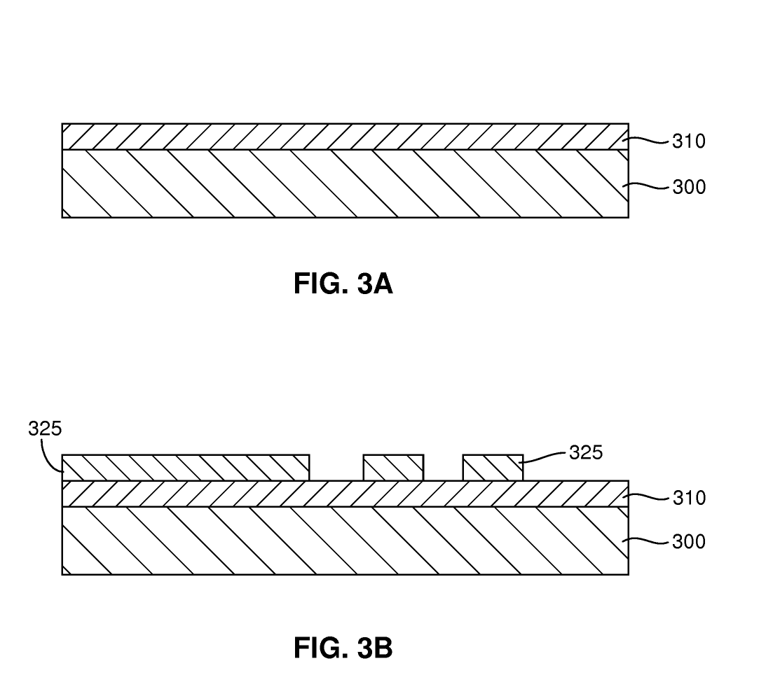

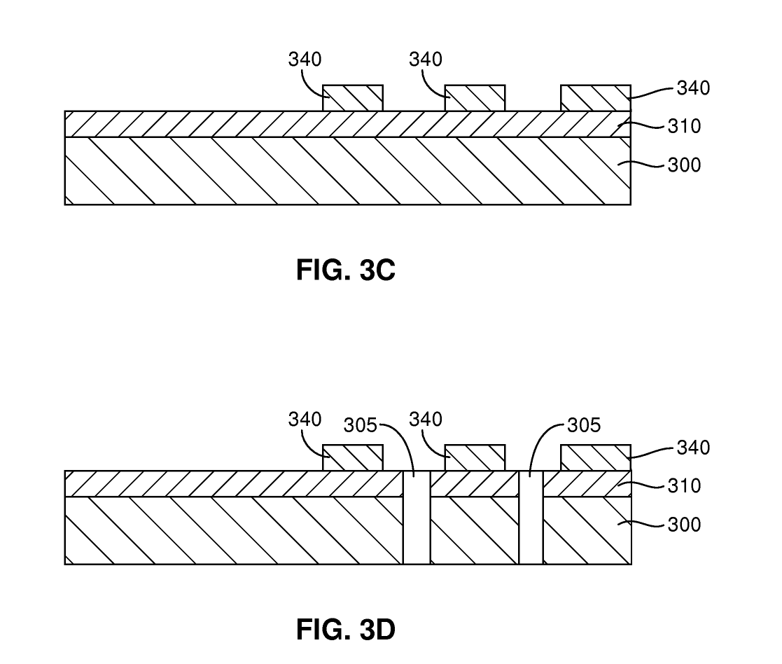

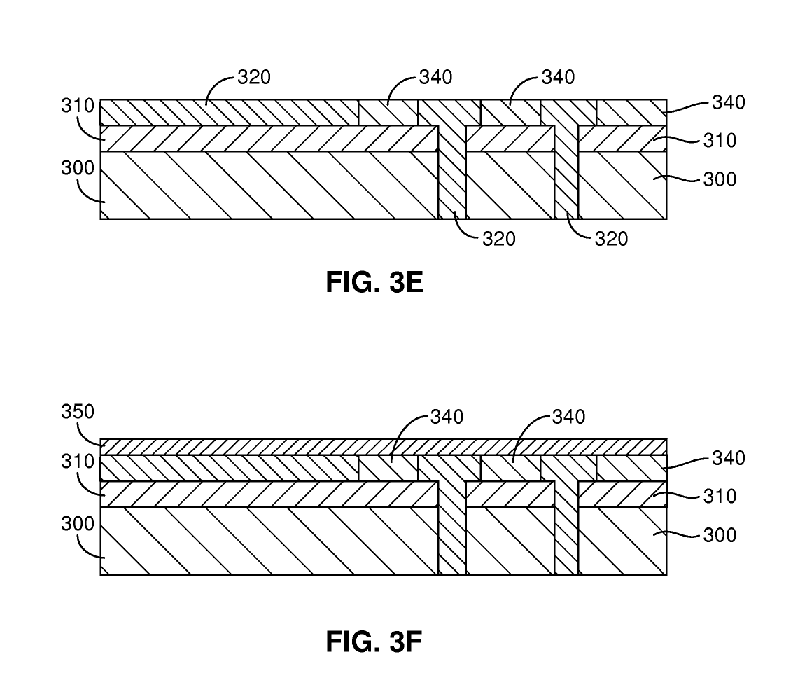

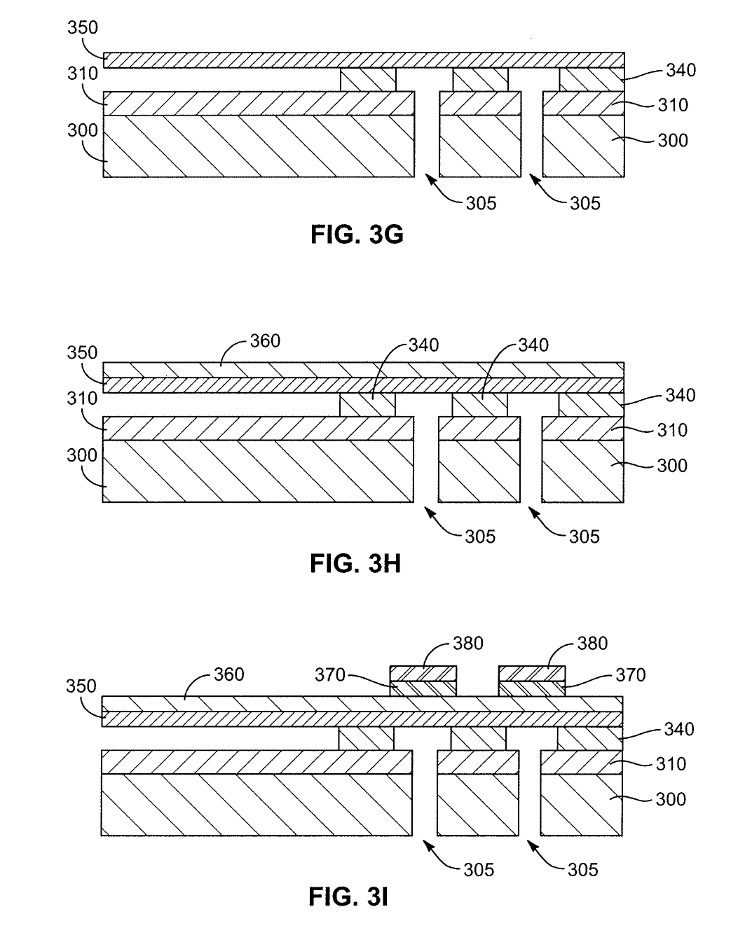

With reference now to FIGS. 3A-3H, an integrated microfabricated fuel cell may be manufactured using a photo resist and a sacrificial polymer. More specifically, FIG. 3A shows a PWB 300 after the deposition of a cathode current collector 310. The cathode current collector 310 may be sized as desired. For example, the cathode current collector 310 may be approximately 100-1000 Å thick. The PWB 300 may be a blank PWB or it may be a pre-fabricated PWB with already defined circuits. The cathode current collector 310 may be sputtered on the surface of the PWB 300 and may include layers of titanium (Ti), gold (Au), copper (Cu), chromium (Cr), tungsten (W), tantalum (Ta), and other appropriate conductors. For example, the cathode current collector 310 may include a 200 Å layer of titanium sputtered directly on the PWB 200 and a 600 Å layer of gold sputtered on the layer of titanium, and another 200 Å layer of titanium sputtered on the gold layer.

With reference to FIG. 3B, to prepare for the formation of channel walls, a photo resist according to those known in the art may be deposited to mask the PWB 300 and the cathode current collector 310. For example, the photo resist 325 may be spin coated on the surface of the current collector 310 layer and developed to produce the desired pattern. The photo resist 325 may be comprised of a commercially available photo resist, such as AZ 4620 available from Hoechst Celanese.

After developing the photo resist 325, the top layer of titanium may be etched away from the exposed region of the current collector 320, thereby revealing the underlying gold layer. As shown in FIG. 3C, channel walls 340 may be built on the underlying gold layer by gold plating. After the channel walls 340 are built up, the photo resist 325 may be removed leaving the channel walls 340 in electrical communication with the cathode current collector 310.

FIG. 3D shows a side view of the microfabricated fuel cell after drilling air holes 305 through the PWB 300 and the cathode current collector 310. The air holes 305 may be configured to allow ambient air to contact the cathode catalyst of the completed microfabricated fuel cell. The air holes 305 may be sized as desired. For example, the air holes 305 may be approximately 20-200 micrometers (μm) wide.

As illustrated by FIGS. 3E and 3F, a sacrificial polymer 320 may be deposited over the exposed cathode current collector 310 and within the air holes 305. As discussed previously, a sacrificial polymer, such as sacrificial polymer 320, may be deposited as a spin coat and comprise a poly(propylene-carbonate) (PPC) and a photoacid generator (PAG) and serve as a temporary placeholder in the microfabrication process. The sacrificial polymer 320 may act as a support for the deposit of a cathode catalyst/glass membrane layer 350. In one embodiment, the cathode catalyst may be deposited by sputtering or painting a prepared catalyst ink containing carbon-supported platinum (Pt) on the surface of the sacrificial polymer 320 and the channel walls 340. Over the cathode catalyst, a layer of P—SiO₂ glass, approximately 6-9 μm thick, may be deposited using a PECVD system.

As shown by FIG. 3G, the sacrificial polymer 320 may be removed by thermal decomposition thereby opening the air holes 305. During thermal decomposition, the sacrificial polymer 320 may be heated in an oven with a temperature ramp up to approximately 190° C. The oxygen from the air may be free to contact the cathode catalyst through the air holes 305 and serve as the oxidant at the cathode of the microfabricated fuel cell.

Referring to FIGS. 3H-3I, a composite membrane layer approximately 15-50 μm thick may be deposited over the cathode catalyst/glass membrane layer 350. For example, a PEM 360 may be deposited by PECVD, over the cathode catalyst/glass membrane layer 350.

With particular reference to FIG. 31, an anode catalyst 370 and an anode current collector 380 may be deposited on the PEM 360 opposite the air holes 305. The anode catalyst 370 may comprise a platinum-ruthenium alloy layer sputter deposited on the surface of the PEM 260 or a carbon-supported Pt—Ru catalyst ink painted on the surface of the PEM 260. The second current collector 280 may include a gold layer deposited on the anode catalyst 270.

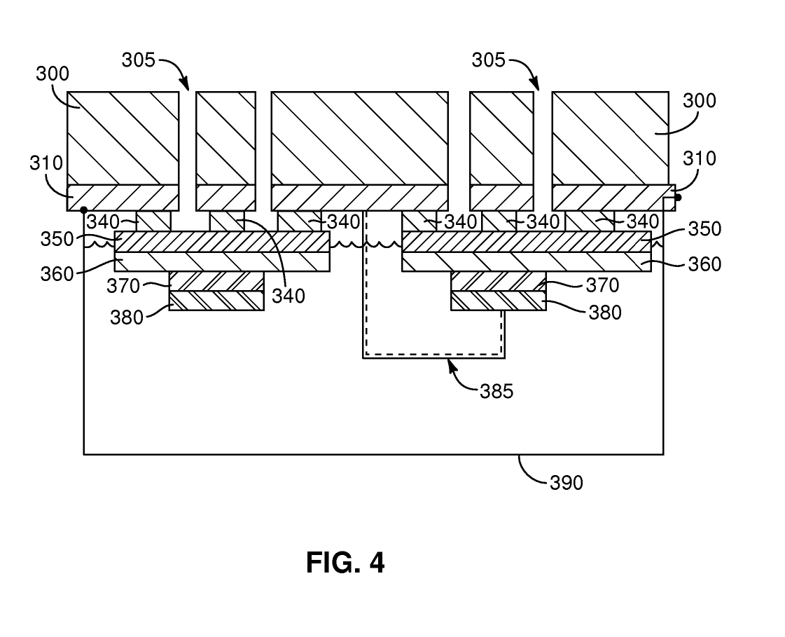

FIG. 4 shows a cross-sectional view of multiple microfabricated fuel cells connected in an electrical series that have been inverted relative to the fuel cell in FIG. 31. In one embodiment, a fuel reservoir, such as fuel reservoir 390, may be attached on the anode side of one or more fuel cells to contain a liquid fuel that is oxidized by the microfabricated fuel cell. For example, an 8-12 molar (M) aqueous methanol solution may be stored within the fuel reservoir 390 and used as fuel to power the microfabricated fuel cell. At the cathode side, the oxygen in the ambient air may be circulated through the air holes 305 and contact the cathode catalyst. The microfabricated fuel cells according to the disclosure, may operate in an inverted configuration with the anode below the cathode, or in the opposite orientation, with the anode a above the cathode.

As known by those of skill the art, the multiple microfabricated fuel cells shown in FIG. 4 may be connected to an electrical load or electrical device in a similar manner as shown in FIG. 31. For example, the external power circuit 385 may include an electrical circuit wiring the multiple microfabricated fuel cells in series by connecting an anode current collector 380 of one cell with the cathode current collector 310 of the next. An electrical device may then be powered by completing a circuit connecting the terminal second current collector 380 in the series with the cathode current collector 310 at the beginning of the series (not shown).

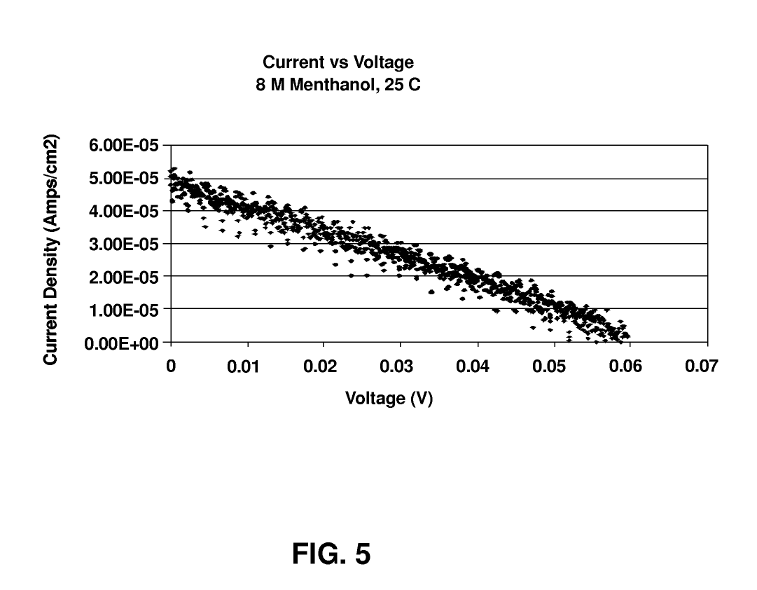

An integrated microfabricated fuel cell constructed according the disclosure may produce significant amounts of electrical power. FIG. 5 shows a Current vs. Voltage curve for one embodiment of an integrated microfabricated fuel cell including a single layer anode catalyst and using an 8 M methanol solution as the fuel and air as the oxidant at room temperature. It can be seen that the microfabricated fuel cell had a high open circuit potential of approximately 0.6 V

It should be emphasized that the described embodiments of this disclosure are merely possible examples of implementations and are set forth for a clear understanding of the principles of this disclosure. Many variations and modifications may be made to the described embodiments of this disclosure without departing substantially from the spirit and principles of this disclosure. All such modifications and variations are intended to be included herein within the scope of this disclosure and protected by the following claims.

1. A method of making a microfabricated fuel cell integrated into a printed circuit board, the method comprising:
depositing at least one cathode current collector on the printed circuit board substrate;
creating at least one air hole through the printed circuit board substrate;
depositing a sacrificial polymer over the surface of the cathode current collector, patterning the sacrificial polymer in order to expose regions of the underlying cathode current collector;
depositing at least one cathode catalyst over the sacrificial polymer;
depositing a proton exchange membrane on the cathode catalyst;
removing the sacrificial polymer layer from between the cathode catalyst and the cathode current collector;
depositing at least one anode catalyst on the proton exchange membrane; and
providing a fuel for oxidation at the anode catalyst.

2. The method of claim 1, wherein the fuel is stored in a fuel reservoir which surrounds the at least one anode catalyst and is below the printed circuit board.

3. The method of claim 1, wherein an anode current collector is deposited on the anode catalyst.

4. The method of claim 1, wherein the anode catalyst includes at least one anode current collector.

5. The method of claim 1, wherein the cathode current collector comprises an electrical conductor selected from the group consisting of titanium, gold, copper, chromium, tungsten, tantalum, and combinations thereof.

6. The method of claim 1, wherein the depositing at least one cathode current collector comprises depositing a layer of titanium followed by a layer of gold.

7. The method of claim 6, wherein the layer of titanium is approximately 200 Å thick and the layer of gold is approximately 600 Å thick.

8. The method of claim 1, wherein the sacrificial polymer comprises at least one poly(propylene-carbonate) and at least one photoacid generator.

9. The method of claim 8, wherein the sacrificial polymer comprises at least 20% by weight of poly(propylene-carbonate) and at least 5% by weight of a photoacid generator.

10. The method of claim 1, wherein the sacrificial polymer is removed by thermal decomposition.

11. The method of claim 1, wherein the sacrificial polymer is a photo-patternable sacrificial polymer.

12. The method of claim 1, wherein the proton exchange membrane comprises a phosphorus doped silicon dioxide glass.

13. The method of claim 1, wherein the proton exchange membrane is deposited using plasma enhanced chemical vapor deposition (PECVD).

14. A method of making a microfabricated fuel cell integrated into a printed circuit board, the method comprising:
depositing at least one cathode current collector on the printed circuit board substrate;
depositing a photo resist mask on the cathode current collector;
patterning the photo resist mask to reveal at least one region of the cathode current collector;
removing the photo resist mask from the cathode current collector;
creating at least one air hole, wherein the air hole extends through the printed circuit board substrate;
depositing a sacrificial polymer over the surface of the cathode current collector;
depositing at least one cathode catalyst over the sacrificial polymer;
depositing a proton exchange membrane on the cathode catalyst;
removing the sacrificial polymer layer from between the cathode catalyst and the cathode current collector;
depositing at least one anode catalyst on the proton exchange membrane; and
providing a fuel for oxidation at the anode catalyst.

15. The method of claim 14, wherein the fuel is stored in a fuel reservoir which is below the printed circuit board.

16. The method of claim 14, wherein the anode catalyst includes an anode current collector.

17. The method of claim 14, wherein an anode current collector is deposited on the anode catalyst.

18. The method of claim 14 further comprising polishing the sacrificial polymer.

19. The method of claim 14, wherein the cathode current collector comprises an electrical conductor selected from the group consisting of titanium, gold, copper, chromium, tungsten, tantalum, and combinations thereof.

20. The method of claim 14, wherein the depositing at least one cathode current collector comprises depositing a first layer of titanium followed by a layer of gold and then followed by a second layer of titanium.

21. The method of claim 20, wherein the first and second layers of titanium are approximately 200 Å thick and the layer of gold is approximately 600 Å thick.

22. The method of claim 14, wherein the sacrificial polymer comprises at least one poly(propylene-carbonate) and at least one photoacid generator.

23. The method of claim 22, wherein the sacrificial polymer comprises at least 20% by weight of poly(propylene-carbonate) and at least 5% by weight of a photoacid generator.

24. The method of claim 14, wherein the sacrificial polymer is removed by thermal decomposition.

25. The method of claim 14, wherein the sacrificial polymer is a photo-patternable sacrificial polymer.

26. The method of claim 14, wherein the proton exchange membrane comprises a phosphorus doped silicon dioxide glass.

27. The method of claim 14, wherein the proton exchange membrane is deposited using plasma enhanced chemical vapor deposition (PECVD).

28. A microfabricated fuel cell integrated into a printed circuit board comprising:
at least one anode comprising an anode current collector deposited on an anode catalyst;
at least one cathode comprising a cathode current collector disposed between the printed circuit board and a cathode catalyst and at least one air hole extending through the printed circuit board and allowing ambient air to contact the cathode catalyst, wherein the cathode current collector is in electrical communication with the anode current collector;
at least one proton exchange membrane in contact with the cathode catalyst, wherein the anode catalyst is deposited on the proton exchange membrane; and
a fuel cell reservoir configured to deliver liquid fuel to the anode.

29. The microfabricated fuel cell of claim 28, wherein the anode is disposed below the printed circuit board.

30. The microfabricated fuel cell of claim 28, wherein the fuel cell reservoir is configured to prevent the liquid fuel from contacting the printed circuit board.

31. An electronic device comprising the microfabricated fuel cell of claim 28.
